(19) United States
(12) Patent Application Publication
(10) Pub. No.: US 2025/0081595 A1
(43) Pub. Date: Mar. 6, 2025

(54) SEMICONDUCTOR DEVICE

(71) Applicant: Renesas Electronics Corporation, Tokyo (JP)

(72) Inventor: Shunichi NAKAMURA, Tokyo (JP)

(21) Appl. No.: 18/780,789

(22) Filed: Jul. 23, 2024

(30) Foreign Application Priority Data
Aug. 31, 2023 (JP) 2023-141068

(51) Int. Cl. H01L 27/06; H01L 29/06; H01L 29/423; H01L 29/739

(52) U.S. Cl. CPC H10D 84/615; H10D 12/481; H10D 62/127; H10D 64/513

(57) ABSTRACT

Improve the reliability of a semiconductor device. A resistive element Rg is filled in a trench TR formed in a well region PW of a semiconductor substrate. The resistive element Rg and the trench TR have an endless shape in plan view. The resistive element Rg is connected to a first contact member PG that is electrically connected to a gate pad GP, and a second contact member PG that is electrically connected to a gate wiring GW. Furthermore, a third contact member PG, which electrically connects an emitter electrode EE to the well region PW, is positioned in an area surrounded by an endless shape of the resistive element Rg, between the first and second contact members PG in a Y direction.

### CROSS-REFERENCE TO RELATED APPLICATIONS

The disclosure of Japanese Patent Application No. 2023-141068 filed on Aug. 31, 2023, including the specification, drawings and abstract is incorporated herein by reference in its entirety.

### BACKGROUND

The present invention relates to semiconductor devices, and more particularly, to semiconductor devices equipped with a resistive element electrically connected to a gate pad.

As power devices, Insulated Gate Bipolar Transistors (IGBTs) with a vertical trench gate structure are known. In the semiconductor devices (semiconductor chips) equipped with power devices, a resistive element is connected to the gate pad as part of a protection circuit to protect the semiconductor device from surge voltages applied to the gate pad.

For example, Japanese Patent Laid-Open No. 2022-82244 (Patent Document 1) discloses a semiconductor device equipped with an IGBT and a resistive element connected to a gate pad. The resistive element is formed on a polysilicon film provided on a semiconductor substrate via an insulating film (silicon oxide film).

### SUMMARY

For example, in motor control systems using three-phase motors, IGBTs are used as drivers for the motors. An emitter electrode of the high-side IGBT and a collector electrode of the low-side IGBT are connected in series.

As disclosed in Patent Document 1, defects may occur in a p-type (second conductivity type) collector region formed on the bottom surface of the semiconductor substrate of the high-side IGBT due to damage during dicing, among other causes. In such cases, when the low-side IGBT is switched at high speed, impact ionization occurs in the high-side IGBT, and carriers (holes) are emitted to the surface side of the semiconductor substrate.

That is, when an emitter potential higher than the potential of the collector electrode is applied to the emitter electrode, the body diode operates, and numerous carriers are generated within the semiconductor substrate. In this state, a potential application is changed, and if apply a collector potential, that is higher than the potential of the emitter electrode, to the collector region, holes are emitted to the upper surface side of the semiconductor substrate. Raising the collector potential makes it difficult for the depletion layer to spread within the semiconductor substrate due to the remaining carriers. Further increasing the collector potential causes the interior of the semiconductor substrate to become a high electric field, resulting in impact ionization. The holes generated by impact ionization are emitted to the surface side of the semiconductor substrate.

At this time, a high potential rise occurs in a p-type well region near the resistive element for the gate pad. Due to this high potential rise, there is a problem that insulation breakdown occurs in the silicon oxide film formed under the resistive element.

The inventors of this application have studied an IGBT in which a trench is formed in the p-type well region, and the resistive element for the gate is formed in the trench with a thin silicon oxide film interposed. The thin silicon oxide film has the same film thickness as a gate insulating film of the IGBT. Compared to the technology described in Patent Document 1, the parasitic resistance of the p-type well region in the trench formation part increases, resulting in a higher potential rise in the p-type well region. Moreover, because a film thickness of the silicon oxide film separating the resistive element and the p-type well region is thin, insulation breakdown of the silicon oxide film is more likely to occur. Therefore, there is a problem that the reliability of the semiconductor device is deteriorated.

Other objects and novel features will become apparent from the description of this specification and the accompanying drawings.

To briefly explain the outline of typical embodiments among the embodiments disclosed in this application, this is as follows.

A semiconductor device according to one embodiment comprises a semiconductor substrate of a first conductivity type having a first main surface, and formed on the first main surface are a gate pad, a gate wiring, and an emitter electrode, and formed on the first main surface is a well region of a second conductivity type different from the first conductivity type, and in the well region, a trench formed in an endless shape in plan view, and in the trench, a resistive element formed in an endless shape in plan view and filled through an insulating film. Furthermore, the semiconductor device comprises a first contact member connected to the resistive element, a second contact member located at a predetermined distance from the first contact member in a first direction, which is the longitudinal direction of the resistive element, and connected to the resistive element, and a third contact member located between the first and second contact members in the first direction in plan view, located in an area surrounded by the inner circumference of the resistive element, and connected to the well region. The gate pad is electrically connected to the resistive element via the first contact member, the gate wiring is electrically connected to the resistive element via the second contact member, and the emitter electrode is electrically connected to the well region via the third contact member.

According to one embodiment, the reliability of the semiconductor device can be improved.

### BRIEF DESCRIPTION OF THE DRAWINGS

FIG. 1 is a plan view showing an entire semiconductor device in a first embodiment.

FIG. 2 is an equivalent circuit diagram of the semiconductor device in the first embodiment.

FIG. 3 is a main portion plan view showing the semiconductor device in the first embodiment.

FIG. 4 is a main portion plan view showing the semiconductor device in the first embodiment.

FIG. 5 is a cross-sectional view showing the semiconductor device in the first embodiment.

FIG. 6 is a cross-sectional view showing the semiconductor device in the first embodiment.

FIG. 7 is a cross-sectional view showing the semiconductor device in the first embodiment.

FIG. 8 is a cross-sectional view showing the semiconductor device in the first embodiment.

FIG. 9 is a main portion plan view showing a semiconductor device in a second embodiment.

FIG. 10 is a main portion plan view showing a semiconductor device in a third embodiment.

FIG. 11 is a main portion plan view showing a semiconductor device in a fourth embodiment.

FIG. 12 is a main portion plan view showing a semiconductor device in a fifth embodiment.

Hereinafter, embodiments are described in detail with reference to the drawings. In all the drawings for explaining the embodiments, the same reference letters denote the same or similar parts, and their repeated description is omitted. Also, in the following embodiments, the description of the same or similar parts is not repeated unless particularly necessary.

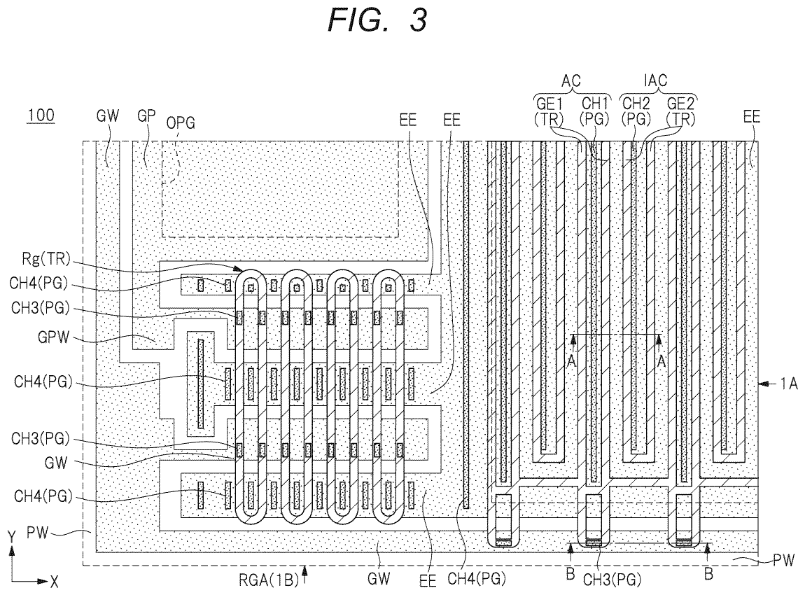

Furthermore, FIGS. 3, 4, 9, 10, 11, and 12 do not accurately represent the vertical relationships between elements in some parts to facilitate understanding of the shapes of the elements.

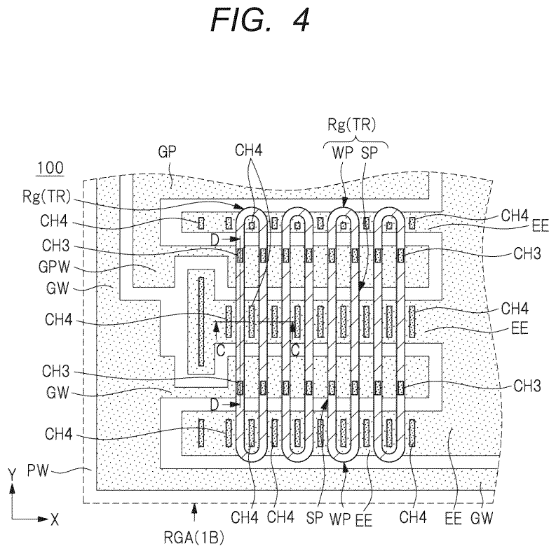

Moreover, in the reference letters of FIGS. 4, 9, 10, 11, and 12, for simplification, CH3 (PG) is represented as CH3, and CH4 (PG) as CH4.

### DETAILED DESCRIPTION

### First Embodiment

### (Structure of Semiconductor Device)

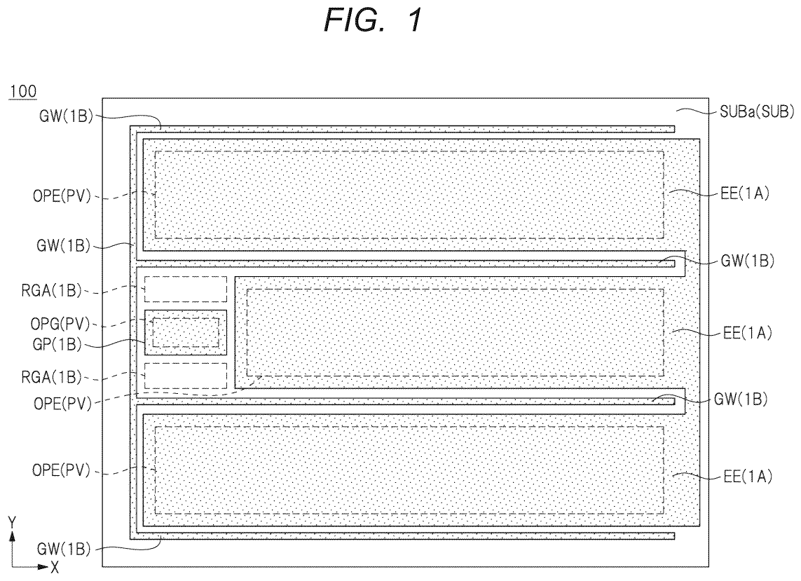

A semiconductor device 100 in a first embodiment will be described below using FIGS. 1 to 8.

FIG. 1 is a plan view showing a semiconductor chip which is the semiconductor device 100.

As shown in FIG. 1, the semiconductor device 100 includes a cell region 1A and a peripheral region 1B. The cell region 1A has formed therein a plurality of cells constituting IGBTs. The plurality of cells are divided, for example, into three cell groups, and a plurality of IGBTs of each cell group are covered with emitter electrodes EE. As shown in FIG. 1, three emitter electrodes EE formed on a t main surface SUBa of a semiconductor substrate SUB extend in a X direction and are located spaced apart in a Y direction. The X direction and the Y direction are directions intersect to each other.

In the peripheral region 1B, a gate pad GP, a gate wiring GW, and a resistive element region RGA are provided. The gate wiring GW is located to surround the parts around the three emitter electrodes EE, the gate pad GP, and the resistive element region RGA, except for the side opposite to the gate pad GP of the emitter electrode EE. The three emitter electrodes EE are connected to each other on the side opposite to the gate pad GP. Also, in the Y direction, the gate wiring GW crosses in the X direction between adjacent the emitter electrode EE and connects to the annular gate wiring GW. As shown in FIG. 1, the gate pad GP and the resistive element region RGA are formed in an area surrounded by the gate wiring GW and the emitter electrode EE. The resistive element region RGA has formed therein a resistive element Rg, which will be described later, and the gate pad GP and the gate wiring GW are electrically connected through the resistive element Rg.

Although not shown, on the first main surface SUBa of the semiconductor substrate SUB, outside the gate wiring GW, annular field plates are formed in multiple layers surrounding the annular gate wiring GW. The emitter electrode EE, the gate pad GP, the gate wiring GW, and field plates are formed by patterning a metal layer in the same manufacturing process on an interlayer insulating film IL described later. Therefore, in plan view, each of the emitter electrode EE, the gate pad GP, and the gate wiring GW is separated from each other without overlapping. Among the field plates, the one at an innermost circumference is integrated with the emitter electrode EE at the part where the three emitter electrodes EE are connected to each other on the side opposite to the gate pad GP, and is separated from the gate wiring GW without overlapping.

Although not shown, the emitter electrode EE, the gate pad GP, the gate wiring GW, and the resistive element subregion RGA is covered with a protective film such as a polyimide film. On part of each of the emitter electrode EE and the gate pad GP, openings OPE and OPG are formed in the protective film. External connection terminals are connected to parts of the emitter electrode EE and the gate pad GP that are exposed from the openings OPE and OPG, thereby electrically connecting the semiconductor device 100 to a lead frame, another semiconductor chip, or a wiring substrate. The external connection terminals are, for example, bonding wires made of gold, copper, or aluminum, or clips made of a copper plate.

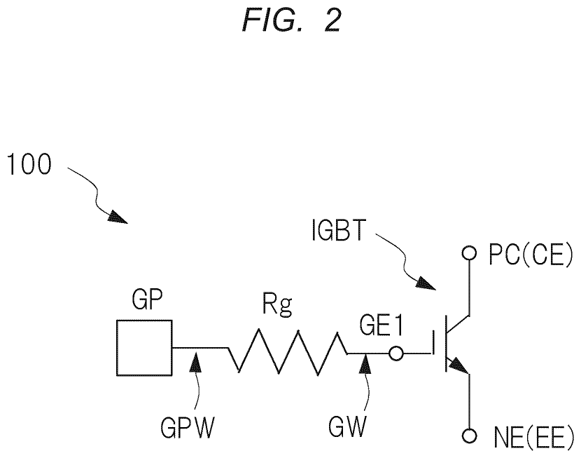

FIG. 2 is an equivalent circuit diagram of the semiconductor device 100. As shown in FIG. 2, the IGBT includes a gate electrode GE1, the collector region PC, and an emitter region NE. A collector electrode CE is connected to the collector region PC, and the emitter electrode EE is connected to the emitter region NE. The gate electrode GE1 is electrically connected to the gate pad GP via the resistive element Rg. Specifically, the gate electrode GE1 is connected to the resistive element Rg via the gate wiring GW, and the gate pad GP is connected to the resistive element Rg via a gate pad wiring GPW.

### (Structure of IGBT)

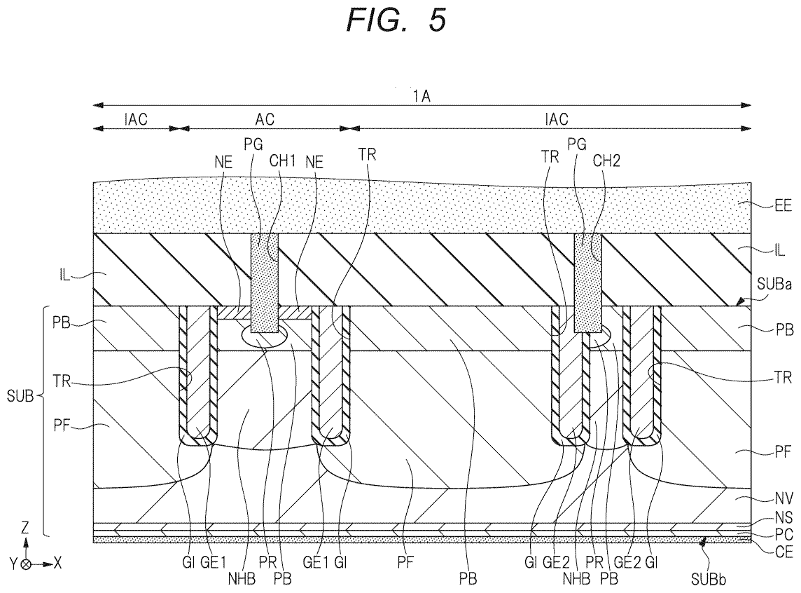

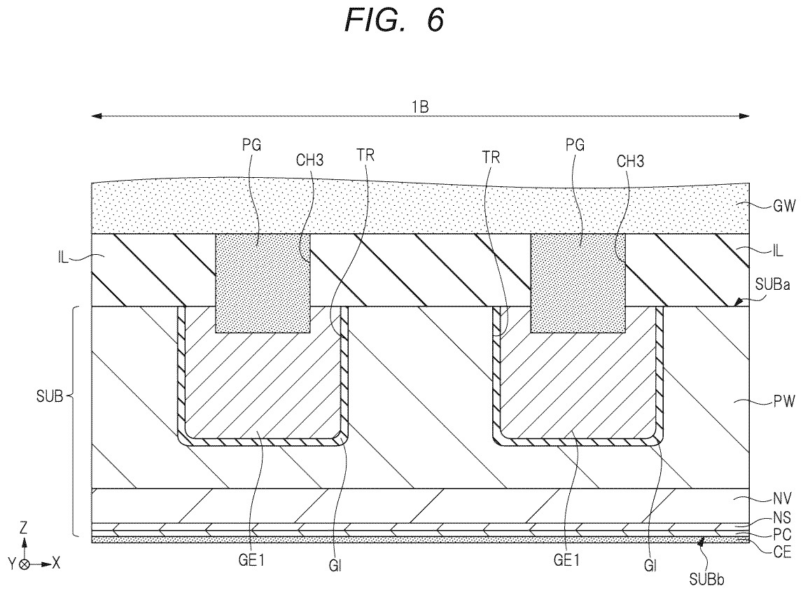

FIG. 3 is a main portion plan view of the cell region 1A and the peripheral region 1B. FIG. 5 is a cross-sectional view along line A-A in FIG. 3. FIG. 6 is a cross-sectional view along line B-B in FIG. 3. The cell region 1A of the semiconductor device 100 has an active cell AC for performing the main operation of the IGBT and an inactive cell IAC other than the active cell AC. In FIG. 3, a shape of a plurality of trenches TR (gate electrodes GE1, GE2, and resistive element Rg), holes CH1, CH2, CH3, and CH4 (contact member PG), the emitter electrode EE, the gate pad GP, the gate pad wiring GPW, the gate wiring GW, and a well region PW are shown.

As shown in FIG. 3, in the cell region 1A, the plurality of trenches TR extend in the Y direction and are adjacent to each other in the X direction. Inside the trench TR of the active cell AC, the gate electrode GEL is formed. Inside the trench TR of the inactive cell IAC, a gate electrode GE2 is formed. A gate trench is constituted by the trench TR formed in the active cell AC and the gate electrode GE1 formed inside it. An emitter trench is constituted by the trench TR formed in the inactive cell IAC and the gate electrode GE2 formed inside it.

A pair of adjacent gate electrodes GE1 of the active cell AC extend into the peripheral region 1B in the Y direction and are electrically connected to the gate wiring GW via a contact member PG formed in the hole CH3. During an operation of the IGBT, a gate potential is supplied to the pair of gate electrodes GE1. The gate electrode GE2 of the inactive cell IAC is electrically connected to the emitter electrode EE via the contact member PG formed in the hole CH2, and an emitter potential is supplied during the operation of the IGBT.

As shown in FIG. 5, the semiconductor device 100 includes the semiconductor substrate SUB with the first main surface (upper surface) SUBa and a second main surface (bottom surface) SUBb. The semiconductor substrate SUB is of an n-type (first conductivity type). Consisting of silicon and having a drift region NV. Here, the n-type semiconductor substrate SUB itself constitutes the drift region NV. The semiconductor substrate SUB may also be a laminated body consisting of an n-type silicon substrate and an n-type silicon layer grown on the silicon substrate by epitaxial growth method while introducing phosphorus (P). In that case, the n-type silicon layer, having a lower impurity concentration than the n-type silicon substrate, constitutes the drift region NV.

On the second main surface SUBb side of the semiconductor substrate SUB, an n-type field stop region (impurity region) NS is formed within the semiconductor substrate SUB. An impurity concentration of the field stop region NS is higher than that of the drift region NV. The field stop region NS is provided to suppress the depletion layer extending from a pn junction on the upper surface side of the semiconductor substrate SUB from reaching the p-type collector region PC during a turn-off of the IGBT.

On the second main surface SUBb side of the semiconductor substrate SUB, the p-type collector region (impurity region) PC is formed within the semiconductor substrate SUB. The collector region PC is located below the field stop region NS.

Below the second main surface SUBb of the semiconductor substrate SUB, the collector electrode CE is formed. The collector electrode CE is electrically connected to the collector region PC and supplies a collector potential to the collector region PC. The collector electrode CE may be a single metal film such as an Au film, Ni film, Ti film, or AlSi film, or a laminated metal film appropriately laminated with these. The field stop region NS, the collector region PC, and the collector electrode CE are formed not only in the cell region 1A but also in the peripheral region 1B and across the entire semiconductor substrate SUB.

On the first main surface SUBa side of the semiconductor substrate SUB, the trench TR is formed within the semiconductor substrate SUB. The trench TR penetrate the emitter region NE and a base region PB and reach the interior of the semiconductor substrate SUB. A depth of the trench TR is, for example, 2 micrometers or more and 5 micrometers or less.

Inside the trench TR, a gate insulating film GI is formed. Inside the trench TR, through the gate insulating film GI, the gate electrodes GE1 and GE2 are filled. The gate insulating film GI is, for example, a silicon oxide film. The gate electrodes GE1 and GE2 are conductive films, for example, polysilicon films (polysilicon films) into which n-type impurities have been introduced. A thickness of the gate insulating film GI is, for example, 70 nanometers or more and 150 nanometers or less.

On the first main surface SUBa side of the semiconductor substrate SUB of the active cell AC, a hole barrier region (impurity region) NHB is formed within the semiconductor substrate SUB between a pair of trenches TR (pair of gate electrodes GE1). An impurity concentration of the hole barrier region NHB is higher than that of the drift region NV.

Within the hole barrier region NHB, the p-type base region (impurity region) PB is formed. Within the p-type base region PB, the n-type emitter region (impurity region) NE is formed. An impurity concentration of the emitter region NE is higher than that of the drift region NV. The base region PB is formed to be shallower than the depth of the trench TR, and the emitter region NE.

It is formed to be shallower than a depth of the base region PB. As shown in FIG. 5, a plurality of emitter regions NE is formed between the pair of trenches TR (pair of gate electrodes GE1), and the base region PB located below the emitter region NE is used as a channel region.

On the first main surface SUBa of the semiconductor substrate SUB of the inactive cell IAC, the hole barrier region NHB is formed in the semiconductor substrate SUB between a pair of trenches TR (pair of gate electrodes GE2). Also, in the semiconductor substrate SUB between the gate electrodes GE1 and GE2, a p-type floating region (impurity region) PF is formed. In the inactive cell IAC, the floating region PF is formed in the semiconductor substrate SUB of the cell region 1A other than between the pair of trenches TR. The p-type base region PB is formed within the hole barrier region NHB and within the floating region PF. A depth of the floating region PF from the first main surface SUBa is slightly deeper than the depth of the trench TR from the first main surface SUBa.

The floating region PF and the base region PB formed within the floating region PF are not electrically connected to the gate wiring GW and the emitter electrode EE and are in an electrically floating state.

In the active cell AC and the inactive cell IAC, the interlayer insulating film IL is formed on the first main surface SUBa of the semiconductor substrate SUB so as to cover each trench TR. The interlayer insulating film IL is, for example, a silicon oxide film. A thickness of the interlayer insulating film IL is, for example, 600 nm or more and 1500 nm or less. Also, the interlayer insulating film IL is subjected to a planarization process to flatten an upper surface of the interlayer insulating film IL.

In the active cell AC, the hole CH1 penetrates through the interlayer insulating film IL and the emitter region NE and reaches the interior of the base region PB. The hole CH1 is formed to contact the emitter region NE and the base region PB.

In the inactive cell IAC, the hole CH2 penetrates through the interlayer insulating film IL and reaches the interior of the base region PB. Also, the hole CH2 is formed to overlap with the gate electrode GE2 in plan view. Therefore, in the inactive cell IAC, the hole CH2 is formed to contact the gate electrode GE2 and the base region PB.

In the active cell AC and the inactive cell IAC, a p-type high concentration diffusion region (impurity region) PR is formed around the bottom of the base region PB of the holes CH1 and CH2. An impurity concentration of the high concentration diffusion region PR is higher than that of the base region PB. The high concentration diffusion region PR is mainly provided to reduce a contact resistance with the contact member PG.

Inside each of the holes CH1 and CH2, the contact members PG are filled. The contact member PG includes a barrier metal film and a conductive film formed on the barrier metal film. The barrier metal film is, for example, a laminated film of a titanium film and a titanium nitride film formed on the titanium film. The conductive film is, for example, a tungsten film. The emitter electrode EE is formed on the interlayer insulating film IL.

The emitter electrode EE is electrically connected to the emitter region NE, the base region PB, the high concentration diffusion region PR, and gate electrode GE2 via the contact member PG, supplying the emitter potential to these regions. Although not shown here, the gate wiring GW, the gate pad wiring GPW, and the gate pad GP, which are formed in the same manufacturing process as the emitter electrode EE, are also formed on the interlayer insulating film IL. The gate wiring GW is electrically connected to the gate electrode GE1 via the contact member PG filled in the hole CH3, supplying the gate potential to the gate electrode GE1.

The emitter electrode EE, the gate wiring GW, the gate pad wiring GPW, and the gate pad GP include the barrier metal film and the conductive film formed on the barrier metal film. The barrier metal film is, for example, a TiW film. The conductive film is, for example, an aluminum alloy film to which copper or silicon has been added. The aluminum alloy film is the main conductor film for the emitter electrode EE and the gate wiring GW, and is sufficiently thicker than the TiW film.

As explained in FIG. 3, the pair of gate electrodes GE1 are interconnected and electrically connected to the gate wiring GW in the peripheral region 1B. As shown in FIG. 6, the well region PW, which is a p-type semiconductor region, is provided in the peripheral region 1B. The gate electrode GE1 formed in the trench TR provided in the well region PW is electrically connected to the gate wiring GW via the contact member PG formed in the hole CH3. The well region PW is formed in the same process as the floating region PF in the cell region 1A, thus having the same depth as the floating region PF. However, in plan view, the well region PW and the floating region PF are physically separated.

### (Resistive Element and its Surrounding Structure)

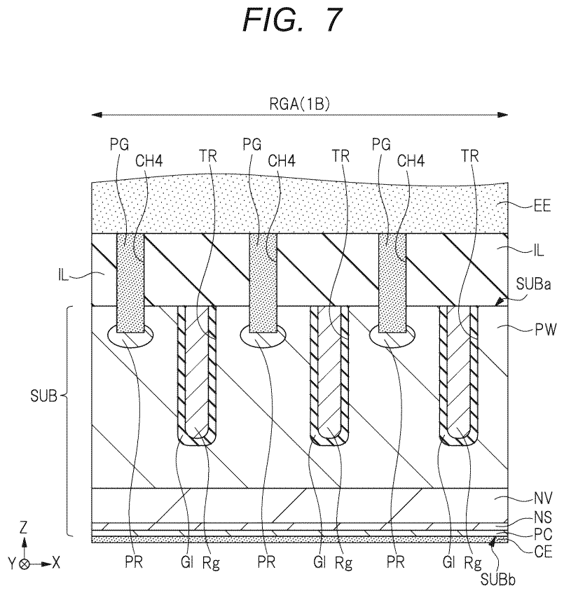

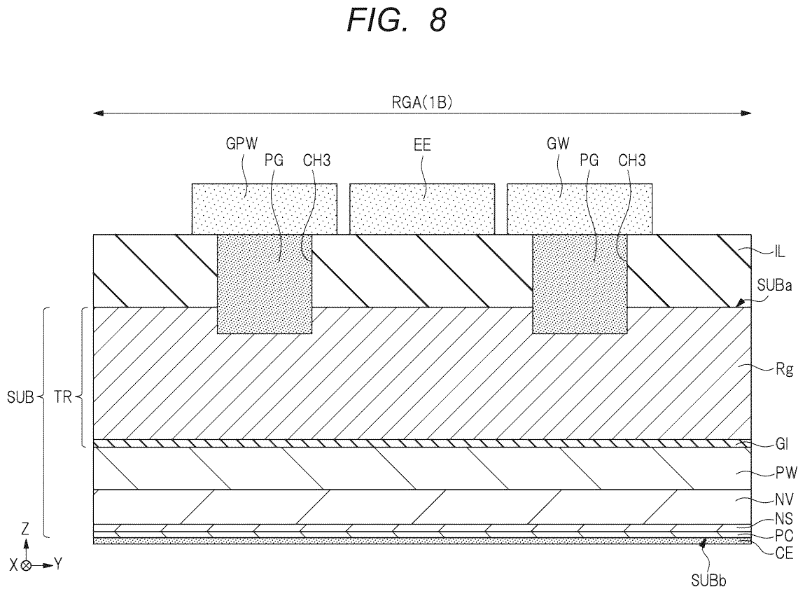

FIG. 4 is a plan view of the resistive element region RGA shown in FIG. 3. FIG. 7 is a cross-sectional view along line C-C in FIG. 4. FIG. 8 is a cross-sectional view along line D-D in FIG. 4. Using FIGS. 3, 4, 7, and 8, the resistive element and its surrounding structure are described.

As shown in FIG. 1, in the semiconductor device 100, two resistive element regions RGA are formed in the Y direction, flanking the gate pad GP. FIG. 3 shows the structure of the resistive element region RGA located below the gate pad GP. The structure of the resistive element region RGA located above the gate pad GP has the same structure as shown in FIG. 3, and the two resistive element regions RGA are symmetrical about the X-axis passing through the center of the gate pad GP in the Y direction.

As shown in FIG. 3, the semiconductor device 100 includes, in the X direction, the above-described cell region 1A and the peripheral region 1B adjacent to the cell region 1A. In plan view, the peripheral region 1B is formed within the well region PW. At the boundary region between the cell region 1A and the peripheral region 1B, the emitter electrode EE formed in the cell region 1A extends into the peripheral region 1B and is electrically connected to the well region PW through the contact member PG formed in the hole CH4. For example, in the central part of FIG. 3, the well region PW is electrically connected to the emitter electrode EE through the contact member PG formed in the elongated hole CH4 in the Y direction. Thus, the region where the emitter electrode EE is electrically connected to the well region PW through the contact member PG is called the well feed section. In other words, carriers (holes) generated by the aforementioned impact ionization enter the well region PW and flow to the emitter electrode EE through the well feed section. Therefore, the farther away from the well feed section, the greater the potential rise of the well region PW.

As shown in FIG. 3, in the Y direction, the peripheral region 1B includes the gate pad GP, the resistive element region RGA located below the gate pad GP, and the gate wiring GW located below the resistive element region RGA. The gate pad GP, in plan view, has a quadrilateral shape (square or rectangle, etc.) with the opening OPG in its central part. The gate pad wiring GPW is connected to the gate pad GP and extends to the resistive element region RGA. The gate pad wiring GPW is a wiring extending from the gate pad GP, and the width of the gate pad wiring GPW is smaller than the length of the side of the gate pad GP (for example, the side from which the gate pad wiring GPW protrudes). The gate wiring GW is located around the gate pad GP and the resistive element region RGA and extends to the resistive element region RGA.

In plan view, the resistive element region RGA is formed within the well region PW. The resistive element region RGA includes a plurality of resistive elements Rg, the plurality of emitter electrodes EE (sometimes referred to as wiring), the gate pad wiring GPW, and the gate wiring GW. As will be described later, the resistive element Rg is filled in the trench TR through the gate insulating film GI. In the description of FIG. 3, the trench TR in which the gate electrode GEL is filled is called the gate trench, but the trench TR in which the resistive element Rg is filled may be called a resistor trench.

As shown in FIG. 4, the resistive element Rg, in a plan view, has an inner and an outer circumference, with the Y direction as a long direction and the X direction as a short direction, forming an endless shape. It can also be said that the resistive element Rg has an annular shape. The resistive element Rg extends in the Y direction and includes two linear portions SP that are separated in the X direction, and two bent sections WP that connect the two linear portions SP. For example, the two linear portions SP extending in the Y direction are located parallel to each other in the X direction, and each of the two bent sections WP has a convex loop shape (arc shape) that extends away from the linear portion SP. The plurality of resistive elements Rg are located at predetermined intervals in the X direction. FIGS. 3 and 4 show four resistive elements Rg. As shown in FIG. 4, in a plan view, the resistive element Rg and the trench TR have the same shape, so the description of the planar shape of the resistive element Rg can be replaced with the description of the planar shape of the trench TR.

As shown in FIG. 4, in a plan view, the gate pad wiring GPW and the gate wiring GW extend in the X direction and are located at predetermined intervals in the Y direction, intersecting with the plurality of resistive elements Rg. Although not limited, the gate pad wiring GPW and the gate wiring GW intersect with the linear portion SP of the resistive element Rg. At the intersection of the gate pad wiring GPW and the resistive element Rg, the resistive element Rg is electrically connected to the gate pad wiring GPW through the contact member PG formed in the hole CH3. Similarly, at the intersection of the gate wiring GW and the resistive element Rg, the resistive element Rg is electrically connected to the gate wiring GW through the contact member PG formed in the hole CH3. The region of the resistive element Rg between the contact member PG connected to the gate pad wiring GPW and the contact member PG connected to the gate wiring GW is a resistance region. As shown in FIG. 8, in the resistance trench, the resistive element Rg is filled in the trench TR formed within the well region PW through the gate insulating film GI. The thickness of the gate insulating film GI of this resistance trench is equal to the thickness of the gate insulating film GI of the above-described gate trench. Also, the depth of the trench TR of the resistance trench is equal to the depth of the trench TR of the above-described gate trench. As shown in FIG. 8, the gate pad wiring GPW and the gate wiring GW are connected to the resistive element Rg through the contact member PG, respectively. The contact member PG is filled in the hole CH3 that penetrates the interlayer insulating film IL formed on the first main surface SUBa of the semiconductor substrate SUB. As shown in FIG. 4, two resistance regions are formed in the resistive element Rg, and the two resistance regions are connected in parallel between the gate pad wiring GPW and the gate wiring GW. Since there are four resistive elements Rg located in the resistive element region RGA, eight resistance regions are connected in parallel between the gate pad wiring GPW and the gate wiring GW. However, a number of the resistive elements Rg and an number of resistance regions can be freely chosen. It should be noted that when using a linear resistive element with both ends instead of an endless resistive element Rg, the inventors of this application have confirmed that a decrease in breakdown voltage or deterioration over time occurs at the ends of the resistive element Rg. Therefore, by using the endless shaped resistive element Rg, it is possible to prevent a decrease in breakdown voltage and deterioration over time between the resistive element Rg and the well region PW.

As shown in FIGS. 3 and 4, in the resistive element region RGA, the three emitter electrodes EE extend in the X direction and are located at predetermined intervals in the Y direction, intersecting with the plurality of resistive elements Rg. For the sake of explanation, the three emitter electrodes EE are referred to as a first emitter electrode EE, a second emitter electrode EE, and a third emitter electrode EE. That is, in the resistive element region RGA, in the Y direction, the first emitter electrode EE, the gate pad wiring GPW, the second emitter electrode EE, the gate wiring GW, and the third emitter electrode EE are located in this order from the gate pad GP side. In the Y direction, the first emitter electrode EE is located between the gate pad GP and the gate pad wiring GPW, the second emitter electrode EE is located between the gate pad wiring GPW and the gate wiring GW, and the third emitter electrode EE is located on the opposite side of the second emitter electrode EE with respect to the gate wiring GW. That is, in the Y direction, the first emitter electrode EE and the second emitter electrode EE are separated by the gate pad wiring GPW, and the second emitter electrode EE and the third emitter electrode EE are separated by the gate wiring GW. Each of the three emitter electrodes EE is electrically connected to the well region PW through the contact member PG formed in the hole CH4, in both an area surrounded by the inner circumference of the endless shaped resistive element Rg and an area adjacent to the outer circumference.

As shown in FIG. 7, the resistive element Rg is filled in the trench TR formed in the well region PW through the gate insulating film GI. In a Z direction, the plurality of trenches TR extend from the first main surface SUBa of the semiconductor substrate SUB towards the interior of the semiconductor substrate SUB (in other words, towards a second main surface SUBb). Here, the Z direction is perpendicular to the first main surface SUBa. The depth of the trench TR is shallower than the depth of the well region PW, but a thin well region PW exists below the trench TR. Compared to a thickness of the well region PW in areas without trench TR, the thickness of the well region PW below the trench TR is very thin. Furthermore, in the Z direction, an impurity concentration at the bottom of the well region PW is lower than an impurity concentration at the surface or middle part of the well region PW. This is because the well region PW is formed using ion implantation and thermal diffusion from the side of the first main surface SUBa. That is, the parasitic resistance of the well region PW located below the trench TR is higher than the parasitic resistance at the surface or middle part of the well region PW. Therefore, in the X direction, a potential difference is likely to occur between the well region PW on both sides of the trench TR. In the present embodiment 1, as shown in FIG. 7, in the X direction, the well region PW is electrically connected to the second emitter electrode EE through the contact member PG filled in the hole CH4, in areas on both sides of the trench TR. Thus, the potential difference of the well region PW in the areas on both sides of the trench TR in the X direction is reduced.

Similarly, in the X direction, in the areas on both sides of the trench TR, the well region PW is electrically connected to the first emitter electrode EE through the contact member PG filled in the hole CH4. Also, in the X direction, in the areas on both sides of the trench TR, the well region PW is electrically connected to the third emitter electrode EE through the contact member PG filled in the hole CH4. In other words, by placing the contact member PG filled in the hole CH4 in the region surrounded by the inner circumference of the endless shaped resistive element Rg and in the region adjacent to the outer circumference, and connecting the well region PW to the emitter electrode EE, the potential difference in the regions on both sides of the trench TR in the well region PW is reduced. Furthermore, this prevents the breakdown of the gate insulating film GI in the trench TR filled with the resistive element Rg.

As shown in FIG. 4, the length of a plurality of holes CH4 and the contact member PG formed in the region surrounded by the inner circumference of the endless shaped resistive element Rg in the Y direction is described. In the Y direction, it is preferable that the length of the hole CH4 and the contact member PG located in the central part is more than twice the length of the hole CH4 and the contact member PG located adjacent to a fold-back portion WP. In FIG. 4, in the Y direction, the length of the contact member PG (in other words, hole CH4) connected to the second emitter electrode EE is more than twice the length of the contact member PG (in other words, hole CH4) connected to the first emitter electrode EE. The carriers generated by the above-described impact ionization are discharged to the emitter electrode EE through the contact member PG, but focusing on the inner circumference region of the endless shaped resistive element Rg, it is necessary to make the discharge amount in the central part more than twice the discharge amount at the fold-back portion WP. In the central part, it is necessary to discharge carriers from the top and bottom directions in the Y direction, while at the fold-back portion WP, it is sufficient to discharge carriers in either the downward or upward direction.

### (Features of the First Embodiment)

The semiconductor device of the first embodiment has the gate trench with the gate electrode GE1 constituting the IGBT embedded, and the resistance trench with the resistive element Rg filled. The depth of the trench TR in the resistance trench is equal to the depth of the trench TR in the gate trench. Also, the thickness of the gate insulating film GI in the resistance trench is equal to the thickness of the gate insulating film GI in the gate trench. By making the structure of the resistance trench similar to that of the gate trench and forming the gate electrode GE1 and the resistive element Rg in the same manufacturing process, manufacturing costs are reduced.

In a plan view, by forming the resistive element Rg and the trench TR an endless shape (for example, annular), it prevents the reduction of breakdown voltage and aging deterioration between the resistive element Rg and the well region PW.

In the region surrounded by the inner circumference of the endless shaped resistive element Rg formed in the well region PW, the well region PW is electrically connected to the emitter electrode EE through the contact member PG formed in the hole CH4.

Thus, the potential fluctuation of the well region PW in the region surrounded by the inner circumference of the endless shaped resistive element Rg is suppressed, and the breakdown of the gate insulating film GI provided in the trench TR formed with the resistive element Rg is prevented. Similarly, in the region adjacent to the outer circumference of the endless shaped resistive element Rg formed in the well region PW, the well region PW is electrically connected to the emitter electrode EE through the contact member PG formed in the hole CH4. Thus, the potential fluctuation of the well region PW in the region adjacent to the outer circumference of the endless shaped resistive element Rg is suppressed, and the breakdown of the gate insulating film GI provided in the trench TR formed with the resistive element Rg is prevented. Here, the region adjacent to the outer circumference includes an area sandwiched between two adjacent endless shaped resistive elements Rg.

In the area surrounded by the inner circumference of the endless shaped resistive element Rg formed within the well region PW, the contact member PG formed in the hole CH4 is positioned in an area adjacent to the linear portion SP of the resistive element Rg and in an area adjacent to the fold-back portion WP, respectively. As shown in FIG. 4, in the Y direction, the length of the hole CH4 and the contact member PG positioned in the area (central part) adjacent to the linear portion SP is more than twice the length of the hole CH4 and the contact member PG adjacent to the fold-back portion WP. In the central part, more than in the fold-back portion WP, by increasing the amount of carrier discharge due to the above-described impact ionization, it is possible to suppress the potential fluctuation of the well region PW in the area surrounded by the inner circumference of the endless shaped resistive element Rg.

### Second Embodiment

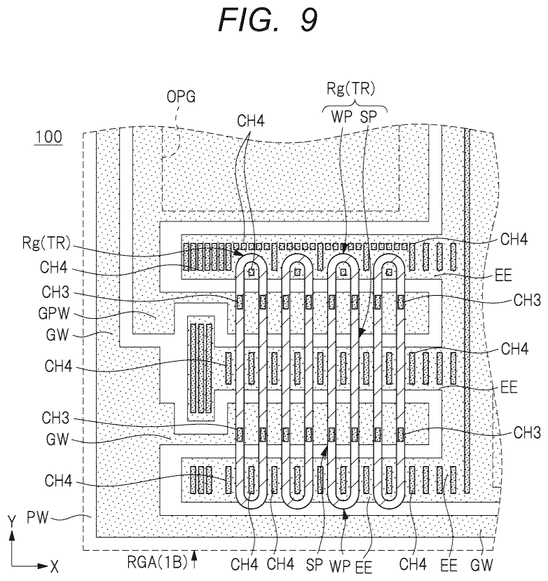

A second embodiment is a modified example of the first embodiment, concerning the arrangement of a hole CH4 and a contact member PG provided in the above-described first emitter electrode EE. In the following description, the differences from the first embodiment are mainly explained, and the points overlapping with the first embodiment are omitted. FIG. 9 is a plan view of the main portion of a semiconductor device 100 of the second embodiment, showing a resistive element region RGA.

As shown in FIG. 9, the width (width in the Y direction) of a first emitter electrode EE is larger than the width of the first emitter electrode EE in the above-described first embodiment. Then, in the Y direction, the hole CH4 and the contact member PG are positioned between a fold-back portion WP of a resistive element Rg and a gate pad GP, connecting a well region PW to the first emitter electrode EE. The gate pad GP has a wide area, so there is a region far from the well feed part under the gate pad GP in the well region PW. With the above-described impact ionization, a potential rise occurs in the well region PW in an area far from the well feed part. In the Y direction, the hole CH4 and the contact member PG are positioned between the fold-back portion WP of the resistive element Rg and the gate pad GP, fixing the potential of the well region PW between the fold-back portion WP and the gate pad GP to the emitter potential. Then, a gate insulating film GI existing in the fold-back portion WP prevents insulation breakdown due to the potential rise.

### Third Embodiment

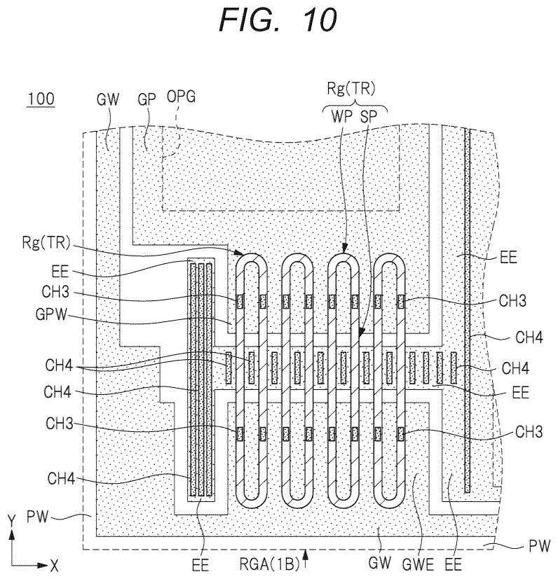

A third embodiment is a modified example of the first embodiment, omitting the above-described first emitter electrode EE and the third emitter electrode EE. In the following description, the focus will be primarily on the differences from the first embodiment, and explanations of aspects that overlap with the first embodiment will be omitted. FIG. 10 is a plan view of the main portion of a semiconductor device 100 of the third embodiment, showing a resistive element region RGA.

As shown in FIG. 10, in the Y direction, a gate pad GP, a gate pad wiring GPW, a second emitter electrode EE, an extending part GWE, and a gate wiring GW are located in this order. In the Y direction, the gate pad wiring GPW extends from the gate pad GP to the resistive element region RGA, covering a part of one of a fold-back portions WP and a linear portion SP of a resistive element Rg. In the Y direction, from the gate wiring GW extending in the X direction, the extending part GWE extends into the resistive element region RGA, covering a part of the other fold-back portion WP and the linear portion SP of the resistive element Rg. In the Y direction, between the gate pad wiring GPW and the extending part GWE of the gate wiring GW, the second emitter electrode EE extends in the X direction. The second emitter electrode EE is electrically connected to a well region PW through a contact member PG formed in a hole CH4, located in an area surrounded by an endless shape resistive element Rg and adjacent to an outer circumference. The gate pad wiring GPW is electrically connected to the resistive element Rg through the contact member PG formed in a hole CH3. The gate pad wiring GPW is electrically connected to the gate pad GP. Similarly, the extending part GWE of the gate wiring GW is electrically connected to the resistive element Rg through the contact member PG formed in the hole CH3. The extending part GWE of the gate wiring GW is electrically connected to the gate wiring GW.

By omitting the above-described first emitter electrode EE and the third emitter electrode EE, compared to the first embodiment, it is possible to widen a wiring width of the gate pad wiring GPW and the gate wiring GW (including the extending part GWE) in the Y direction. Therefore, the variable range of the length of the resistive element region RGA of the resistive element Rg in the Y direction can be increased.

Furthermore, in the resistive element region RGA where a plurality of resistive elements Rg is located, the second emitter electrode EE includes a first portion that crosses a central part of the resistive element Rg in a long direction (Y direction) in a short direction (X direction), and a second portion that extends along the long direction of the resistive element Rg in a peripheral part of the resistive element region RGA. The second portion branches from the first portion and extends in the Y direction beyond the positions where the gate pad wiring GPW and the resistive element Rg are connected, and where the extending part GWE of the gate wiring GW and the resistive element Rg are connected. The wiring width of the second portion in the Y direction is larger than that of the first portion in the Y direction. In the X direction, the first portion of the second emitter electrode EE has a plurality of holes CH4 and a plurality of contact members PG located. The first portion of the second emitter electrode EE is electrically connected to the well region PW through the plurality of contact members PG formed in the plurality of holes CH4. Similarly, the second portion of the second emitter electrode EE has the plurality of holes CH4 and the plurality of contact members PG located, extending in the Y direction. And, the second portion of the second emitter electrode EE is electrically connected to the well region PW through the plurality of contact members PG formed in the plurality of holes CH4. Thus, by providing the second portion extending in the Y direction on the second emitter electrode EE and bringing the well feed section closer to the fold-back portion WP of the resistive element Rg, it is possible to prevent insulation breakdown of a gate insulating film GI in a resistance trench.

### Fourth Embodiment

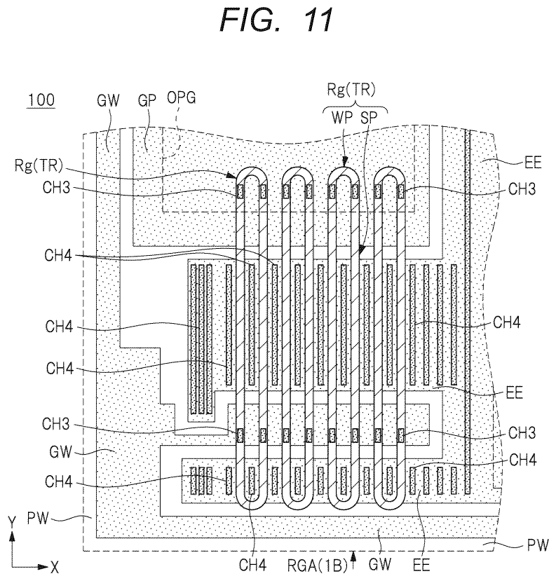

A fourth embodiment is a modified example of the first embodiment, omitting the above-described first emitter electrode EE and a gate pad wiring GPW. In the following description, mainly the differences from the first embodiment will be explained, and the points overlapping with the first embodiment will be omitted. FIG. 11 is a plan view of the main portion of a semiconductor device 100 of the fourth embodiment, showing a resistive element region RGA.

As shown in FIG. 11, in the Y direction, a gate pad GP, a second emitter electrode EE, a gate wiring GW, and a third emitter electrode EE are located in this order. In the Y direction, the gate pad GP covers a part of one fold-back portion WP and a linear portion SP of a resistive element Rg. The gate pad GP is electrically connected to the resistive element Rg through a contact member PG formed in a hole CH3. In plan view, a part of one fold-back portion WP and the linear portion SP of the resistive element Rg may be located within an opening OPG.

By omitting the above-described first emitter electrode EE and the gate pad wiring GPW, the width of the second emitter electrode EE in the Y direction can be increased compared to the first embodiment. And, in the Y direction, the length of the contact member PG formed in a hole CH4, which is electrically connected to the second emitter electrode EE and a well region PW, is increased. Therefore, the ability of the second emitter electrode EE to discharge carriers in the above-described impact ionization can be improved, and an insulation breakdown of a gate insulating film GI at the fold-back portion WP of the resistive element Rg located under the gate pad GP can be prevented.

However, in the well region PW under the gate pad GP, there exists an area (in other words, an area where the potential rise is significant) that is distant from the well feed section. Therefore, in the Y direction, it is preferable to place the fold-back portion WP of the resistive element Rg within a region less than 300 micrometers from the contact member PG connected to the second emitter electrode EE. Considering the parasitic resistance of the well region PW, insulation breakdown of the gate insulating film GI can be prevented in areas less than 300 micrometers from the well feed section.

Furthermore, by extending a resistive element Rg under the gate pad GP to the end, the linear portion SP of the resistive element Rg can be made longer in the Y direction, and the variable range of a resistance region can be increased.

### Fifth Embodiment

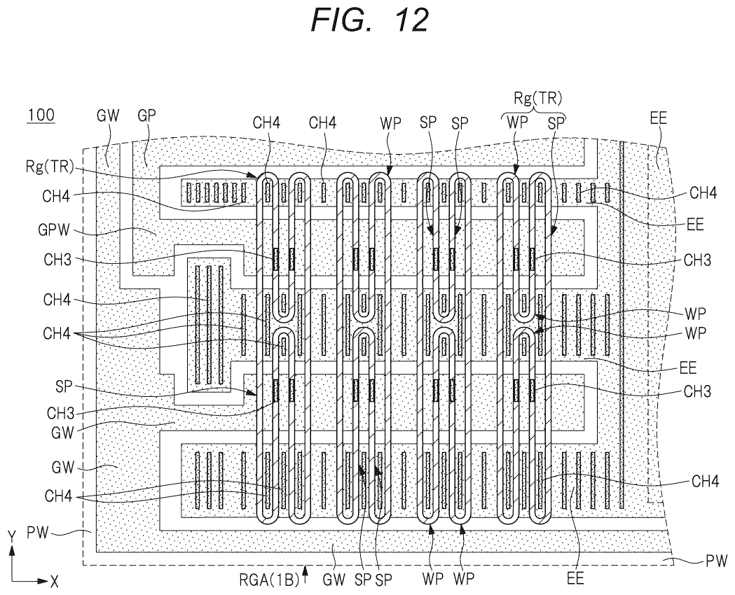

A fifth embodiment is a modified example of the first embodiment, concerning the shape of a resistive element Rg. In the following description, mainly the differences from the first embodiment will be explained, and the points overlapping with the first embodiment will be omitted. FIG. 12 is a plan view of the main portion of a semiconductor device 100 of the fifth embodiment, showing a resistive element region RGA.

Similar to the first embodiment, in the resistive element region RGA, in the Y direction, from a gate pad GP side, a first emitter electrode EE, a gate pad wiring GPW, a second emitter electrode EE, a gate wiring GW, and a third emitter electrode EE are located in order. And, in FIG. 12 as indicated, the resistive element Rg comprises first and second linear portions SP that extend continuously from the first emitter electrode EE to the third emitter electrode EE in the Y direction. Furthermore, the first and second linear portions SP are parallel to each other and are spaced apart by a predetermined distance in the X direction.

Moreover, the resistive element Rg includes third and fourth linear portions SP, which are located parallel and adjacent to each other between the first and second linear portions SP. The third and fourth linear portions SP extend continuously from the first emitter electrode EE to the second emitter electrode EE in the Y direction. Additionally, the resistive element Rg comprises fifth and sixth linear portions SP, which are located parallel and adjacent to each other between the first and second linear portions SP. The fifth and sixth linear portions SP extend continuously from the second emitter electrode EE to the third emitter electrode EE in the Y direction. In the Y direction, the third and fifth linear portions SP are located linearly, as are the fourth and sixth linear portions SP.

Furthermore, the resistive element Rg includes first, second, third, fourth, fifth, and sixth fold-back portions WP. The first fold-back portion WP connects the first and third linear portions SP. The second fold-back portion WP connects the third and fourth linear portions SP in an area overlapping with the second emitter electrode EE. The third fold-back portion WP connects the fourth and second linear portions SP. The fourth fold-back portion WP connects the first and fifth linear portions SP. The fifth fold-back portion WP connects the fifth and sixth linear portions SP in the area overlapping with the second emitter electrode EE. The sixth fold-back portion WP connects the sixth and second linear portions SP. The first and third fold-back portions WP are each positioned in an area overlapping or adjacent to the first emitter electrode EE. The first and third fold-back portions WP may also span an area from overlapping to adjacent to the first emitter electrode EE. The fourth and sixth fold-back portions WP are each positioned in an area overlapping or adjacent to the third emitter electrode EE. The fourth and sixth fold-back portions WP may also span an area from overlapping to adjacent to the third emitter electrode EE.

In an area enclosed by an inner circumference of the resistive element Rg and an area adjacent to its outer circumference, a well region PW is electrically connected to the first emitter electrode EE through a contact member PG formed in a hole CH4, adjacent to the first and third fold-back portions WP. In an area enclosed by the inner circumference of the resistive element Rg and the area adjacent to its outer circumference, the well region PW is electrically connected to the second emitter electrode EE through the contact member PG formed in the hole CH4, adjacent to the second and fifth fold-back portions WP. In the area enclosed by the inner circumference of the resistive element Rg and the area adjacent to its outer circumference, the well region PW is electrically connected to the third emitter electrode EE through the contact member PG formed in the hole CH4, adjacent to the fourth and sixth fold-back portions WP. Thus, the well region PW is electrically connected to the third emitter electrode EE.

The resistive element Rg is in an area overlapping the gate pad wiring GPW, at the first or third linear portions SP, electrically connected to the gate pad wiring GPW through the contact member PG formed in a hole CH3. Furthermore, the resistive element Rg, in an area overlapping the gate wiring GW, is electrically connected to the gate wiring GW through the contact member PG formed in the hole CH3 at the first or fifth linear portions SP. FIG. 12 shows an example where the gate pad wiring GPW is electrically connected to the third linear portion SP and the gate wiring GW is connected to the fifth linear portion SP. In the resistive element Rg, the area where the gate pad wiring GPW and the gate wiring GW are electrically connected can be varied, allowing for an increased range of variability in the resistance area.

As described above, the present invention has been explained based on the embodiment, but it is not limited to this embodiment and can be variously modified without departing from the gist of the invention.

For example, in the above embodiment, an IGBT is exemplified as a device formed in a cell region 1A, but the technology disclosed in the embodiment is not limited to IGBTs and can also be applied to power MOSFETs with a vertical trench gate structure.

Moreover, the material used for the semiconductor substrate SUB is not limited to silicon (Si) and may be silicon carbide (SiC), gallium nitride (GaN), or gallium oxide (Ga2O3).

What is claimed is:

1. A semiconductor device comprising:
a semiconductor substrate of a first conductivity type having a first main surface;
a gate pad, a gate wiring, and an emitter electrode formed on the first main surface;
a well region of a second conductivity type opposite to the first conductivity type formed on the first main surface;
a first trench formed in an endless shape on the well region in plan view;
a first resistive element formed in an endless shape in plan view such that the first resistive element is filled in the first trench via a first insulating film;
a first contact member connected to the first resistive element;
a second contact member spaced apart from the first contact member in a first direction, which is a long direction of the first resistive element, and connected to the first resistive element; and
a third contact member located between the first contact member and the second contact member in the first direction and positioned within an area surrounded by an inner circumference of the first resistive element, and connected to the well region, wherein
the gate pad is electrically connected to the first resistive element via the first contact member,
the gate wiring is electrically connected to the first resistive element via the second contact member, and
the emitter electrode is electrically connected to the well region via the third contact member.

2. The semiconductor device according to claim 1, further comprising:
a fourth contact member located between the first and second contact members in the first direction and positioned in an area adjacent to an outer circumference of the first resistive element, and connected to the well region.

3. The semiconductor device according to claim 2, further comprising:
a fifth contact member electrically connected to the gate pad and the first resistive element, and
a sixth contact member electrically connected to the gate wiring and the first resistive element, and located at a predetermined interval from the fifth contact member in the first direction, wherein
the first resistive element includes:
first and second linear portions extended in the first direction and adjacent to each other in a second direction which is a short direction of the first resistive element; and
first and second fold-back portions are spaced apart from each other in the first direction and connected to the first and second linear portions,
the first contact member is connected to the first fold-back portion or the first linear portion,
the second contact member is connected to the second fold-back portion or the first linear portion,
the fifth contact member is connected to the first fold-back portion or the second linear portion, and
the sixth contact member is connected to the second fold-back portion or the second linear portion.

4. The semiconductor device according to claim 3, wherein
the third and fourth contact members are located adjacent to the first linear portion of the first resistive element in the first direction.

5. The semiconductor device according to claim 3, wherein
a shape of the first resistive element is annular in plan view.

6. The semiconductor device according to claim 3, wherein
the first resistive element includes
a first resistance region located between the first and second contact members, and
a second resistance region located between the fifth and sixth contact members, and
the first and second resistance regions are electrically connected in parallel between the gate pad and the gate wiring.

7. The semiconductor device according to claim 3, further comprising:
a first wiring extended along the second direction and connected to the first and fifth contact members,
a second wiring extended along the second direction and connected to the second and sixth contact members, and
a third wiring extended along the second direction and connected to the third and fourth contact members, wherein
the first wiring is electrically connected to the gate pad,
the second wiring is electrically connected to the gate wiring,
the third wiring is electrically connected to the emitter electrode, and
the third wiring is located between the first and second wirings without overlapping with the first and second wirings in the first direction.

8. The semiconductor device according to claim 7, further comprising:
a fourth wiring located between the first wiring and the gate pad in the first direction and extended in the second direction and electrically connected to the emitter electrode;
a plurality of seventh contact members electrically connecting the fourth wiring to the well region;
a fifth wiring located on an opposite side of the third wiring relative to the second wiring in the first direction and extended in the second direction, and electrically connected to the emitter electrode; and
a plurality of eighth contact members electrically connecting the fifth wiring to the well region.

9. The semiconductor device according to claim 8, wherein
the plurality of seventh contact members contacts the first fold-back portion and is located within the area surrounded by the inner circumference of the first resistive element and in the area adjacent to the outer circumference of the first resistive element, and
the plurality of eighth contact members contacts the second fold-back portion and is located within the area surrounded by the inner circumference of the first resistive element and in the area adjacent to the outer circumference of the first resistive element.

10. The semiconductor device according to claim 9, wherein
a part of the plurality of seventh contact members is located between the first fold-back portion and the gate pad.

11. The semiconductor device according to claim 9, wherein
a length of the third contact member is more than twice a length of the seventh contact member adjacent to the first fold-back portion in the area surrounded by the inner circumference of the first resistive element in the second direction.

12. The semiconductor device according to claim 7, wherein
the first wiring continuously extends from the gate pad in the first direction,
the first fold-back portion, a part of the first linear portion, and a part of the second linear portion are overlapped with the first wiring in plan view, and
the first and fifth contact members are overlapped with the first wiring in plan view.

13. The semiconductor device according to claim 3, wherein
the first fold-back portion, a part of the first linear portion, and a part of the second linear portion are overlapped with the first wiring in plan view, and
the first and fifth contact members are overlapped with the first wiring in plan view.

14. The semiconductor device according to claim 3, further comprising:
second and third trenches formed outside of the well region in a plan view;
a first gate electrode formed in the second trench via a second insulating film;
a second gate electrode formed in the third trench via a third insulating film;
an emitter region of the first conductivity type formed on the first main surface in an area between the second and third trenches;
a base region of the second conductivity type formed in the semiconductor substrate and contacted to the emitter region in the area between the second and third trenches;
a drift region of the first conductivity type formed in the semiconductor substrate and contacted to the base region
a collector region of the second conductivity type formed on a second main surface of the semiconductor substrate opposite to the first main surface
a ninth contact member electrically connecting the first and second gate electrodes to the gate wiring.

15. The semiconductor device according to claim 14, wherein
a depth of the first trench from the first main surface is equal to a depth of the second trench or the third trench from the first main surface.

16. The semiconductor device according to claim 15, wherein a thickness of the first insulating film is equal to a thickness of the second and third insulating films.

17. The semiconductor device according to claim 14, wherein
the first resistive element, the first and second gate electrodes include a polysilicon film.

18. The semiconductor device according to claim 14, further comprising:
an interlayer insulating film formed on the first main surface to cover the well region, the first resistive element, the first and second gate electrodes, wherein
the first, second, fifth, and sixth contact members penetrate through the interlayer insulating film and connect to the first resistive element,
the third and fourth contact members penetrate through the interlayer insulating film and connect to the well region, and
the ninth contact member penetrates through the interlayer insulating film and connects to the first and second gate electrodes.

19. The semiconductor device according to claim 3, further comprising:
a fourth trench formed in an endless shape on the well region in plan view;
a second resistive element formed in an endless shape in plan view such that the second resistive element is filled in the second trench via a fourth insulating film, wherein
the fourth trench is located adjacent to the first trench in the second direction,
the first resistive element and the second resistive element are electrically connected in parallel between the gate pad and the gate wiring.

20. A semiconductor device comprising:
a semiconductor substrate of a first conductivity type having a main surface;
a gate pad, a gate wiring, and an emitter electrode formed on the main surface;
a well region of a second conductivity type opposite to the first conductivity type formed on in the main surface;
a first trench formed in an endless shape on the well region in plan view;
a first resistive element formed in an endless shape in plan view such that the first resistive element is filled in the first trench via a first insulating film;
a first contact member connected to the first resistive element;
a second contact member spaced apart from the first contact member in a first direction, which is a long direction of the first resistive element, and connected to the first resistive element; and
a third contact member located between the first and second contact members in the first direction and positioned within an area surrounded by an inner circumference of the first resistive element, and connected to the well region, wherein
the gate pad is electrically connected to the first resistive element via the first contact member,
the gate wiring is electrically connected to the first resistive element via the second contact member,
the emitter electrode is electrically connected to the well region via the third contact member,
the first resistive element includes:
first and second linear portions extended in the first direction and adjacent to each other in a second direction which is a short direction of the first resistive element;
third, fourth, fifth and sixth linear portions extended in the first direction and spaced apart from each other in the second direction in an area between the first and second linear portions;
a first fold-back portion connecting the first and third linear portions;
a second fold-back portion connecting the third and fourth linear portions;
a third fold-back portion connecting the fourth and second linear portions;
a fourth fold-back portion connecting the first and fifth linear portions;
a fifth fold-back portion connecting the fifth and sixth linear portions; and
a sixth fold-back portion connecting the sixth and second linear portions,
a length of the third, fourth, fifth and sixth linear portions are shorter than a length of the first and second linear portions,
the third and fifth linear portions are linearly located in the first direction, and
the fourth and the sixth linear portions are linearly located in the first direction.
